(19) United States
(12) Patent Application Publication
(10) Pub. No.: US 2008/0069952 A1
(43) Pub. Date: Mar. 20, 2008

(54) METHOD FOR CLEANING A SURFACE OF A SEMICONDUCTOR SUBSTRATE

(75) Inventors: Thomas S. Moss, Colorado Springs, CO (US); Mark A. Good, Colorado Springs, CO (US)

Correspondence Address: SCHNECK & SCHNECK, P.O. BOX 2-E, SAN JOSE, CA, 95109-0005, US

(73) Assignee: ATMEL CORPORATION, San Jose, CA (US)

(21) Appl. No.: 11/532,850

(22) Filed: Sep. 18, 2006

(51) Int. Cl. C23C 16/00

(52) U.S. Cl. 427/248.1; 427/255.4

(57) ABSTRACT

A method of cleaning and oxidizing a substrate, for example, a silicon wafer, and forming a film (e.g., silicon dioxide) in-situ by placing the substrate in a chamber, pumping-down the chamber to a predetermined subatmospheric pressure, and elevating a temperature of the substrate within the chamber. Cleaning begins by releasing hydrogen gas into the chamber for a time period of, for example, 5 seconds to 300 seconds. The hydrogen gas, along with any contaminants, are then evacuated from the chamber. Prior to removing the substrate, an oxidant, such as oxygen (O₂), steam or another process (e.g., an in-situ steam generation (ISSG) process) is then released into the chamber and the film is formed on a surface of the substrate.

### TECHNICAL FIELD

The present invention relates generally to semiconductor processing techniques and more specifically to a method of cleaning and preparing a semiconductor substrate for subsequent oxidation steps.

### BACKGROUND ART

In advanced integrated circuit (IC) processing, near atomically clean substrate surfaces are necessary prior to formation of films subsequently grown or deposited over the surfaces. In general terms, if the surface is not properly prepared to be sufficiently clean before growth or deposition of surface-critical films, contact/via resistances may be too high, poor adhesion between layers of material may result wherein IC reliability is reduced, retarded film formation may occur (e.g., a silicide may never properly form), and/or poor texture (e.g., microroughness) and/or grain structure may result in the film. Specifically, with regard to cleaning techniques and methods described herein, gate oxides, for example, may have poor electrical characteristics.

A typical wet-bench cleaning operation uses various aqueous-based chemicals. The chemicals frequently contain various combinations of hydrofluoric or hydrochloric acid, deionized water, ammonium hydroxide, ammonium fluoride, or hydrogen peroxide (an “RCA-type” cleaning procedure). Wet-bench cleaning is performed as an ex-situ operation and thus, requires transport through an ambient environment to, for example, a rapid-thermal processor or tube furnace for a thermal-oxide growth step. Any intervening exposure to the ambient environment forces a native oxide growth. Even though the native oxide is thin (typically 8 Å-20 Å depending upon exposure time, presence of oxygen or water vapor, ambient temperature, etc.), the oxide is invariably non-uniform. Consequently, subsequent film formation steps will be adversely affected. The native oxide growth is especially deleterious in fabricating floating gate transistors where gate oxide thicknesses are approaching native oxide thicknesses. Additionally, certain chemicals such as ammonium hydroxide, NH₄OH, can have particularly deleterious effects on surface microroughness characteristics. Although a more dilute form of NH₄OH will reduce microroughness levels, the dilute solution is commensurately less effective at removal of residual organics and particulate matter.

Contemporary IC manufacturers frequently clean a substrate ex-situ prior to moving the substrate into a process tool (e.g., a diffusion furnace or cluster tool) for subsequent process steps. However, an ex-situ clean allows contamination to accumulate as well as native oxide to form on surfaces of the substrate prior to the subsequent steps occurring.

Alternatively, a first chamber of the cluster tool may be used for substrate surface cleaning and a second separate chamber for film growth or deposition. In this alternative case, a substrate, for example, a silicon wafer, is first positioned within the cleaning chamber in order to clean surfaces of the substrate. The substrate is then moved from the cleaning chamber to a separate film growth/deposition chamber to form a required film on the previously-cleaned substrate surface.

However, even this two-chamber process is disadvantageous for several reasons. First, any time a substrate is transferred between chambers, even in a cluster tool, there is a tendency for the surface of the substrate to become contaminated with harmful contaminants such as heavy metals. Further, there is also a tendency for the surface to become oxidized by exposure to an oxidation ambient (e.g., oxygen or water vapor) during the transfer. Any oxidation or contamination of the surface can result in factors such as poor device interconnect conductivity, poor film adhesion, asperities in thin films, and so on. Additionally, purchase, maintenance, and operation of two separate chambers is expensive and a resultant reduction in throughput of substrates through a two-chamber system adversely increases IC manufacturing costs.

Therefore, a need exists in the industry for a method to adequately clean and maintain surfaces of substrates prior to subsequent film formation processes in a single chamber.

### SUMMARY

In an MOS circuit, an electrical potential applied to a gate electrode of a transistor capacitively couples charge to a channel region of a transistor and control current that flows between source and drain regions of a transistor. A gate electrode is electrically insulated from the channel by a gate dielectric. In silicon CMOS fabrication operations, thin dielectric layers (e.g., the gate dielectric or tunnel dielectrics), have historically utilized silicon dioxide (SiO₂) formed by thermal oxidation of silicon in the channel region. Silicon dioxide as a dielectric material has many advantages, including an ability to be removed from a surface of a substrate by etching with either gas-, plasma-, or liquid-based chemicals.

However, one inevitable consequence of integrated circuit (IC) fabrication is a formation of contaminant residues on surfaces of semiconductor substrates. Two major categories of contaminants are organic contaminant residues and metal ion contaminant residues. Both types of contaminant residues may cause fabrication problems when the residues are allowed to remain on surfaces which are subsequently exposed to additional semiconductor processes. Contaminant residues have a particularly deleterious effect on thin oxides formed through thermal processes.

For example, organic contaminant residues are commonly known to result from incomplete removal of photoresists or other organic polymer layers from the surfaces of semiconductor substrates. Organic contaminant residues may carbonize to yield a conductive carbon residue. The conductive carbon residue may be difficult to remove and may compromise electrical integrity of the semiconductor substrate upon which it is formed.

In contrast with organic contaminants, metal ion contaminant residues may be formed from several sources within an IC fabrication process, including but not limited to: (1) partial dissolution and re-deposition of metals from conductor layers, and (2) introduction of metal ions as a consequence of their presence as trace impurities within solvents and photoresist materials through which ICs are processed. Metal ion contaminant residues are particularly troublesome in early stages of thermal oxidation processing of advanced Metal Oxide Semiconductor Field Effect Transistors (MOSFETs). Since thin gate oxides and shallow diffusion layers are present in MOSFET devices, the devices are particularly susceptible to degradation when impregnated with metal-ion contaminant residues.

The present invention is particularly well-suited to cleaning substrates in the semiconductor and allied-industries (e.g., data storage, disk media, thin film head (TFH) production, etc.). Exemplary embodiments described herein will focus on cleaning and oxidizing substrates used in the semiconductor industry, with a focus on specific embodiments comprising silicon wafers. However, one of skill in the art will recognize an applicability to the allied fields. Additionally, although exemplary embodiments are described in terms of pre-oxidation cleaning methodologies, the method is equally applicable to cleaning partially-processed substrates prior to diffusion, alloying, post-implant annealing, and various other fabrication steps.

In a specific exemplary embodiment, the present invention is a method of cleaning and forming a silicon dioxide film on a silicon wafer in-situ by placing the wafer in a chamber, pumping-down the chamber to a predetermined subatmospheric pressure, and elevating a temperature within the chamber. Cleaning begins by releasing hydrogen gas into the chamber for a time period of 5 seconds to 300 seconds. The hydrogen gas, along with any contaminants, are then evacuated from the chamber. Prior to removing the wafer, an oxidant, such as oxygen (O₂) or steam, is then released into the chamber and the silicon dioxide film is formed on the wafer.

### BRIEF DESCRIPTION OF THE DRAWINGS

FIG. 1 is a simplified representation of a reactor chamber.

FIG. 2 is an exemplary process flow diagram of substrate cleaning and oxidation steps.

### DETAILED DESCRIPTION

The cleaning method described herein, in an exemplary embodiment, involves a hydrogen-reduction process for removal of native oxide, organic contaminants, and metal contaminants from a surface of a silicon wafer. Depending upon a cleanliness level of incoming starting materials (e.g., silicon wafers or other substrates), a standard RCA-type clean may be used for removal of, for example, particulate contaminants and other gross impurities prior to the hydrogen-reduction process. The hydrogen-reduction process may therefore, in particular applications, be combined with a standard wet-cleaning process.

The method is partially based on a chemical reaction between the silicon dioxide and the hydrogen, thus taking advantage of a reducing effect of hydrogen. For example, when a native oxide film, SiOₓ is exposed to hydrogen, H₂, inside a process chamber, the chemical reaction breaks the native oxide down into silane, SiH₄, and water, H₂O, such that

SiOₓ+ [symbol] SiH₄+H₂O+H₂

(Note that native oxide frequently contains dangling bonds such that an SiO₂ composition may be only partially formed. Thus, the reaction shown is not fully balanced.)

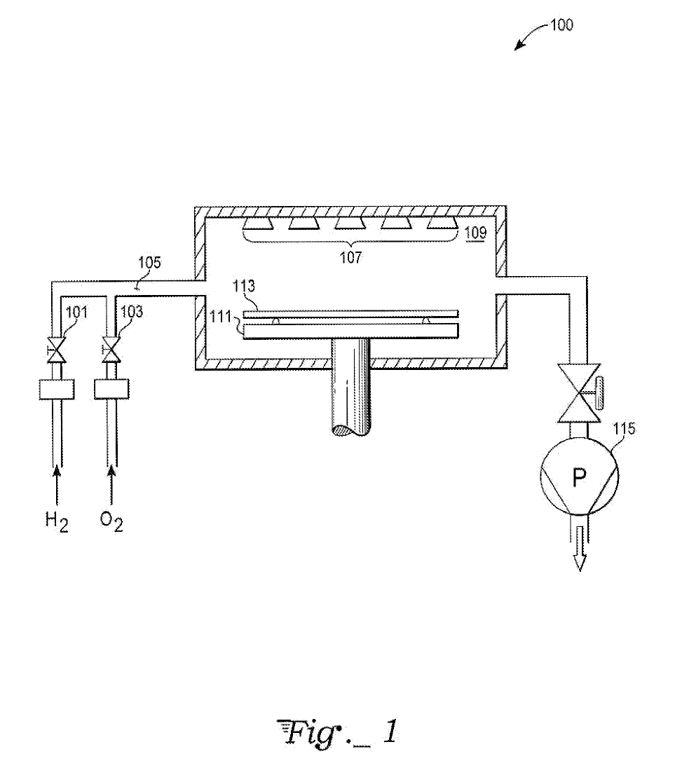

With reference to FIG. 1, an exemplary reactor chamber 100 includes hydrogen, H₂, and oxygen, O₂, source gases, a hydrogen butterfly valve 101, an oxygen butterfly valve 103, a distribution line 105, a series of lamp-type heaters 107, a process chamber 109, a substrate platen 11, a substrate 113, and a pump 115.

Although the source gases are shown as pure hydrogen and oxygen, one skilled in the art will recognize that other precursor gases that are hydrogen-containing or oxygen-containing may be used and properly fractionated or dissociated as needed. Additionally, any appropriate oxidant may be utilized in place of the oxygen source such as, for example, steam. Also, pure O₂ or steam may be diluted with an inert gas, such as nitrogen. Alternatively, a percentage of H₂ (approximately 1% to 33% by volume) injected into an oxygen ambient in a reduced pressure system produces oxygen and/or hydroxyl radicals and oxidizes using these species (in-situ-steam-generation, ISSG). Further, although this exemplary embodiment refers to use of a reactor chamber, the method of the present invention is equally applicable to rapid thermal process (RTP) furnaces, vertical and horizontal tube furnaces, and other oxidation tools known in the industry.

In a specific exemplary embodiment, the substrate 113 is a silicon wafer. In this embodiment, the silicon wafer is placed onto the platen 11 and the process chamber 109 is pumped down to a subatmospheric pressure, of approximately 3 Torr to 20 Torr, or in certain applications, to a range of about 5 Torr to 6 torr. In other embodiments, ranges extending from 3 Torr to 300 Torr are contemplated. The oxygen butterfly valve 103 is initially closed and the hydrogen butterfly valve 101 is open. Although particular gas flow rates are not critical, particular oxygen flow rates that work in a specific chamber type are from 5 to 15 liters/minute with a hydrogen glow rate of 1% to 33% of the oxygen flow rate. The hydrogen gas enters the process chamber 109 and flows over the face of the silicon wafer. The hydrogen reduction process, as with most chemical reactions, becomes more efficient at elevated temperatures. In this embodiment, temperatures in a range of 750° C. to 1150° C. are employed. The wafer may either be heated by the lamp-type heaters 107 (e.g., tungsten-halogen lamps in light pipes) or through the substrate platen 111 (e.g., a resistive heating element—not shown). Hydrogen removes hydroxyls from a surface of the silicon wafer and reduces any elemental or compound metallic atoms or molecules as well as reduces any organic and inorganic contaminants. The hydrogen gas is typically left in the process chamber 109 for anywhere from 5 to 300 seconds, after which the process chamber 109 is evacuated through the pump 115. (A skilled artisan will recognize that the pump may be a series of pumps, such as a roughing pump and a turbomolecular pump although such details are not critical for application of the present invention.) After the process chamber 109 is evacuated, the silicon wafer 113 is oxidized. To oxidize the silicon wafer 113, the hydrogen butterfly valve 101 is closed and the oxygen butterfly valve 103 is opened (although any of the oxidation techniques described herein may be readily employed). Notice that the silicon wafer 113 has not been disturbed and remains in the process chamber 109, thereby preventing formation of any native oxide. Oxygen is allowed to flow as needed until a silicon dioxide film (not shown) formed on the silicon wafer is of a desired thickness.

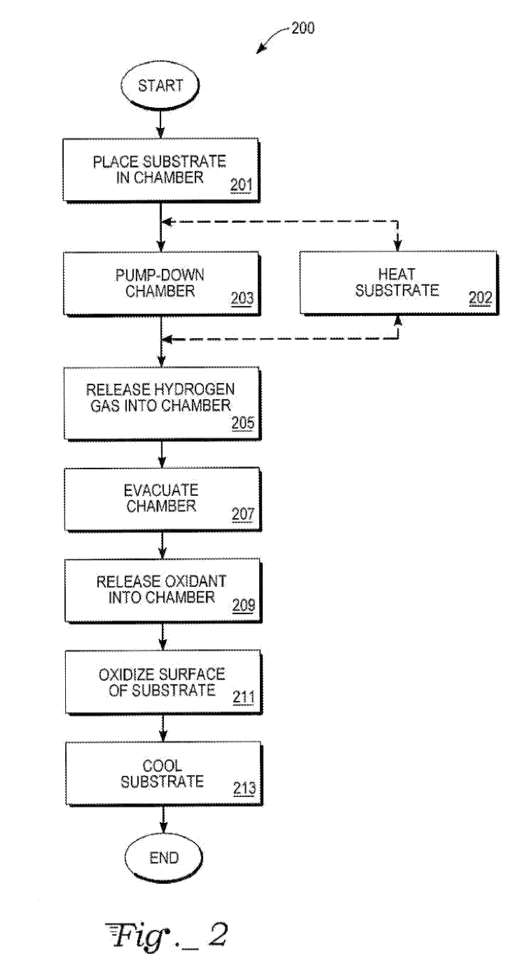

The process flow chart 200 of FIG. 2 includes exemplary steps of placing 201 a substrate in a chamber and pumping 203 down the chamber to a desired pressure level. The substrate may be heated 202 either immediately after being placed 201 in the chamber or after the chamber is pumped 203 down. Once the pressure in the chamber has reached the desired level, hydrogen is released 205 into the chamber. After the hydrogen has been allowed to interact with a surface of the substrate (for example, after a period of time from 5 seconds to 300 seconds), the chamber is evacuated 207. The evacuation step 207 removes any remaining hydrogen gas, released contaminants from the surface of the substrate, and any gas molecules (e.g., SiH₄, H₂O) that were formed in the reduction process. While the wafer is still in-situ, an oxidant (e.g., steam or oxygen; alternatively other processes, such as ISSG described supra, are amenable as well) is released 209 into the chamber to oxidize 211 the surface of the substrate, thus forming an insulating film. Common films, discussed supra, include silicon dioxide formed on silicon wafers. The substrate is then allowed to cool 213.

In the foregoing specification, the present invention has been described with reference to specific embodiments thereof. It will, however, be evident to a skilled artisan that various modifications and changes can be made thereto without departing from the broader spirit and scope of the invention as set forth in the appended claims. For example, skilled artisans will appreciate the methods described herein are not exclusive and may be supplemented by other cleaning methodologies and techniques. The specification and drawings are, accordingly, to be regarded in an illustrative rather than a restrictive sense.

What is claimed is:

1. A method of cleaning and forming a film on a substrate, the method comprising:
placing the substrate in a single processing chamber;
pumping-down the single processing chamber to a predetermined subatmospheric pressure;
elevating a temperature of the substrate within the single processing chamber;
releasing hydrogen gas into the single processing chamber;
evacuating the hydrogen gas from the single processing chamber; and
forming a film on a surface of the substrate prior to removing the substrate from the single processing chamber.

2. The method of claim 1 wherein the substrate is a silicon wafer.

3. The method of claim 2 wherein the film formed is silicon dioxide.

4. The method of claim 1 wherein the predetermined subatmospheric pressure is in a range of approximately three Torr to 300 Torr.

5. The method of claim 1 wherein the predetermined subatmospheric pressure is in a range of approximately three Torr to 20 Torr.

6. The method of claim 1 wherein the predetermined subatmospheric pressure is in a range of approximately five Torr to six Torr.

7. The method of claim 1 wherein the temperature is in a range from 750° C. to 1150° C.

8. The method of claim 1 further comprising releasing an oxidant into the chamber after the step of evacuating the hydrogen gas from the chamber.

9. The method of claim 8 wherein the oxidant is oxygen.

10. The method of claim 8 wherein the oxidant is steam.

11. The method of claim 8 wherein the oxidant is produced by an in-situ steam generation process.

12. The method of claim 1 further comprising a step of wet-cleaning the substrate prior to placing the substrate in the chamber.

13. A method of cleaning and oxidizing a silicon wafer, the method comprising:
placing the silicon wafer in a chamber;
pumping-down the chamber to a predetermined subatmospheric pressure;
elevating a temperature of the silicon wafer within the chamber;
releasing hydrogen gas into the chamber;
evacuating the hydrogen gas from the chamber;
releasing an oxidant into the chamber; and
forming a silicon dioxide film on a surface of the silicon wafer prior to removing the silicon wafer from the chamber.

14. The method of claim 13 wherein the predetermined subatmospheric pressure is in a range of approximately three Torr to 300 Torr.

15. The method of claim 13 wherein the predetermined subatmospheric pressure is in a range of approximately three Torr to 20 Torr.

16. The method of claim 13 wherein the predetermined subatmospheric pressure is in a range of approximately five Torr to six Torr.

17. The method of claim 13 wherein the temperature is in a range from 750° C. to 1150° C.

18. The method of claim 13 wherein the oxidant is oxygen.

19. The method of claim 13 wherein the oxidant is steam.

20. The method of claim 13 wherein the oxidant is produced by an in-situ steam generation process.

21. The method of claim 13 further comprising a step of wet-cleaning the silicon wafer prior to placing the silicon wafer in the chamber.

22. A method of cleaning and oxidizing a silicon wafer, the method comprising:
placing the silicon wafer in a chamber;
pumping-down the chamber to a predetermined subatmospheric pressure;
elevating a temperature of the silicon wafer within the chamber;
releasing hydrogen gas into the chamber for a predetermined time period;
evacuating the hydrogen gas and any contaminants from the chamber;
releasing an oxidant into the chamber; and
forming a silicon dioxide film on a surface of the silicon wafer prior to removing the silicon wafer from the chamber.

23. The method of claim 22 wherein the predetermined subatmospheric pressure is in a range of approximately three Torr to 300 Torr.

24. The method of claim 22 wherein the predetermined subatmospheric pressure is in a range of approximately three Torr to 20 Torr.

25. The method of claim 22 wherein the predetermined subatmospheric pressure is in a range of approximately five Torr to six Torr.

26. The method of claim 22 wherein the predetermined time period is in a range of 5 seconds to 300 seconds.

27. The method of claim 22 wherein the temperature is in a range from 750° C. to 1150° C.

28. The method of claim 22 wherein the oxidant is oxygen.

29. The method of claim 22 wherein the is steam.

30. The method of claim 22 wherein the oxidant is produced by an in-situ steam generation process.

31. The method of claim 22 further comprising a step of wet-cleaning the silicon wafer prior to placing the silicon wafer in the chamber.
